(19) United States
(12) Patent Application Publication
(10) Pub. No.: US 2019/0363048 A1
(43) Pub. Date: Nov. 28, 2019

(54) VIA PREFILL IN A FULLY ALIGNED VIA

(71) Applicant: Lam Research Corporation, Fremont, CA (US)

(72) Inventors: Lie Zhao, Lake Oswego, OR (US); Artur Kolics, Lake Oswego, OR (US); Yezdi Dordi, Palo Alto, CA (US)

(21) Appl. No.: 15/986,661

(22) Filed: May 22, 2018

(51) Int. Cl. H01L 23/522; H01L 21/768; H01L 21/02

(52) U.S. Cl. CPC H01L 23/5226; H01L 21/76813; H01L 21/76877; H01L 21/02362; H01L 21/76846

(57) ABSTRACT

An electrically conductive structure in an integrated circuit (IC) includes a bottom metal line and a top metal line with via providing electrical interconnection between the bottom metal line and the top metal line. The via is fully aligned with both the bottom metal line and the top metal line. An electrically conductive material fills an opening formed in a dielectric material to form the via, and the electrically conductive material is directly in contact with the bottom metal line. No diffusion barrier layer and/or liner layer is between the bottom metal line and the via.

### BACKGROUND

Semiconductor devices may be formed in a multi-level arrangement with electrically conductive structures in different levels insulated from each other by one or more intervening layers of dielectric material. The formation of electrically conductive structures in the semiconductor devices can be achieved using damascene or dual damascene processes. Trenches and/or holes are etched into the dielectric material and may be lined with one or more liner layers and barrier layers. Electrically conductive material may be deposited in the trenches and/or holes to form vias, contacts, or other interconnect features that extend through the dielectric material and provide electrical interconnection between the electrically conductive structures.

The background provided herein is for the purposes of generally presenting the context of the disclosure. Work of the presently named inventors, to the extent that it is described in this background, as well as aspects of the description that may not otherwise qualify as prior art at the time of filing, are neither expressly nor impliedly admitted as prior art against the present disclosure.

### SUMMARY

Provided herein is an apparatus with a via in an electrically conductive structure. The apparatus includes a first dielectric layer, a first metal line formed in the first dielectric layer, a second dielectric layer over the first metal line and the first dielectric layer, and a second metal line formed in the second dielectric layer or over the second dielectric layer. The apparatus further includes a via extending through the second dielectric layer and electrically connecting the first metal line and the second metal line, where the via is fully aligned with the first metal line and the second metal line, and where the via includes an electrically conductive material directly in contact with the first metal line.

In some implementations, each of the first metal line, the second metal line, and the electrically conductive material of the via includes copper or copper alloy. In some implementations, the first metal line is recessed below a top surface of the first dielectric layer. In some implementations, the apparatus further includes a conformal dielectric layer disposed over the first dielectric layer and the first metal line, where the conformal dielectric layer is between the first dielectric layer and the second dielectric layer. The apparatus may further include a selective dielectric layer disposed on the first dielectric layer so that the first metal line is recessed below a top surface of the selective dielectric layer, where the conformal dielectric layer is disposed on the selective dielectric layer and has an etch selectivity of greater than about 10:1 with respect to the selective dielectric layer. The via may be disposed in a trench and an opening extending through the second dielectric layer and the conformal dielectric layer, where the opening extends from a bottom of the trench to a top surface of the first metal line. In some implementations, the electrically conductive material of the via directly contacts the first metal line without a diffusion barrier layer and/or a liner layer between the via and the first metal line. In some implementations, the second dielectric layer includes a low-k dielectric material having a dielectric constant of less than about 4.0. The low-k dielectric material may include a porous organosilicate glass (OSG). In some implementations, the apparatus further includes a self-formed barrier layer at an interface between the second dielectric layer and the via, wherein the electrically conductive material of the via includes a copper alloy. In some implementations, the via is partially landed on the first metal line to provide landed portions on the first metal line and unlanded portions outside the first metal line.

Another aspect involves a method of manufacturing an electrically conductive structure. The method includes receiving a substrate with a first metal line in a first region of the substrate, a selective dielectric layer in a second region outside the first region of the substrate, a conformal dielectric layer on the second dielectric layer and the first metal line, and an interlayer dielectric over the first metal line, the conformal dielectric layer, and the selective dielectric layer, where the conformal dielectric layer has an etch selectivity equal to or greater than about 10:1 with respect to the selective dielectric layer. The method further includes forming a via through the interlayer dielectric and the conformal dielectric layer to a top surface of the first metal line, where the via includes an electrically conductive material directly in contact with the first metal line.

In some implementations, the method further includes forming a second metal line over the first metal line, wherein the via provides electrical interconnection between the second metal line and the first metal line. Each of the first metal line, the second metal line, and the via may include a copper or copper alloy. In some implementations, forming the via includes forming a trench and an opening through the interlayer dielectric and the conformal dielectric layer, where the opening extends from a bottom of the trench to the top surface of the first metal line, and filling the opening with the electrically conductive material to form the via. In some implementations, filling the opening with the electrically conductive material includes depositing, by electroless deposition, the electrically conductive material on the first metal line.

Another aspect involves a method of manufacturing an electrically conductive structure. The method includes receiving a substrate with a first metal line in a first region of the substrate that is recessed below a top surface of the substrate, a conformal dielectric layer on the first metal line and the top surface of the substrate, and an interlayer dielectric over the first metal line and the conformal dielectric layer, where the conformal dielectric layer has an etch selectivity equal to or greater than about 10:1 with respect to an underlying dielectric material of the substrate. The method further includes forming a via through the interlayer dielectric and the conformal dielectric layer to a top surface of the first metal line, where the via includes an electrically conductive material directly in contact with the first metal line.

In some implementations, the method further includes forming a second metal line over the first metal line, where the via provides electrical interconnection between the second metal line and the first metal line. Each of the first metal line, the second metal line, and the via may include a copper or copper alloy. In some implementations, the method further includes forming a trench and an opening through the interlayer dielectric and the conformal dielectric layer, where the opening extends from a bottom of the trench to the top surface of the first metal line, and filling the opening with the electrically conductive material to form the via. In some implementations, filling the opening with the electrically conductive material includes depositing, by electroless deposition, the electrically conductive material on the first metal line.

These and other aspects are described further below with reference to the drawings.

### BRIEF DESCRIPTION OF THE DRAWINGS

FIGS. 1A-1E show cross-sectional schematic illustrations of an example fabrication of semiconductor device structures using a dual damascene fabrication process according to some implementations.

FIG. 2 shows a cross-sectional schematic illustration of an unlanded interconnect feature for an electrically conductive structure.

FIGS. 3A-3C show cross-sectional schematic illustrations of an example process of forming a fully aligned via for connecting metal lines according to some implementations.

FIGS. 4A-4C show cross-sectional schematic illustrations of an example process of forming a fully aligned via for connecting metal lines according to some other implementations.

FIG. 5 shows a cross-sectional schematic illustration of an example electrically conductive structure with a via that is a fully aligned via and that is in direct contact with a metal line according to some implementations.

FIG. 6 shows a cross-sectional schematic illustration of an example electrically conductive structure with a via that is a fully aligned via and that is in direct contact with a metal line according to some other implementations.

FIG. 7A shows a plot of time dependent dielectric breakdown lifetime as a function of increasing electric fields for silicon oxide dielectric layers having a barrier layer and without a barrier layer.

FIG. 7B shows a plot of time dependent dielectric breakdown lifetime as a function of increasing electric fields for organosilicate glass dielectric layers having a barrier layer and without a barrier layer.

FIGS. 8A-8C show cross-sectional schematic illustrations of an example dual damascene fabrication process with a copper via in direct contact with a copper line according to some implementations.

FIGS. 9A-9B show cross-sectional schematic illustrations of an example fabrication process for a copper alloy via in direct contact with a copper line and a self-formed barrier layer according to some implementations.

FIG. 10 shows a flow diagram of an example method of manufacturing an electrically conductive structure of an integrated circuit according to some implementations.

FIG. 11 shows a flow diagram of an example method of manufacturing an electrically conductive structure of an integrated circuit according to some implementations.

### DETAILED DESCRIPTION

In the present disclosure, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication thereon. A wafer or substrate used in the semiconductor device industry typically has a diameter of 200 mm, or 300 mm, or 450 mm. The following detailed description assumes the present disclosure is implemented on a wafer. However, the present disclosure is not so limited. The work piece may be of various shapes, sizes, and materials. In addition to semiconductor wafers, other work pieces that may take advantage of the present disclosure include various articles such as printed circuit boards and the like.

### INTRODUCTION

Fabrication of electrically conductive structures in semiconductor devices often involves metal wiring that connect to one another. The electrically conductive structures may include line features (e.g., metal lines or metallization layers) that traverse a distance across a chip, and interconnect features (e.g., vias) that connect the line features in different levels. The line features may include copper lines and the interconnect features may include copper vias. The line features and interconnect features may be insulated by interlayer dielectrics (ILD) which are electrical insulators.

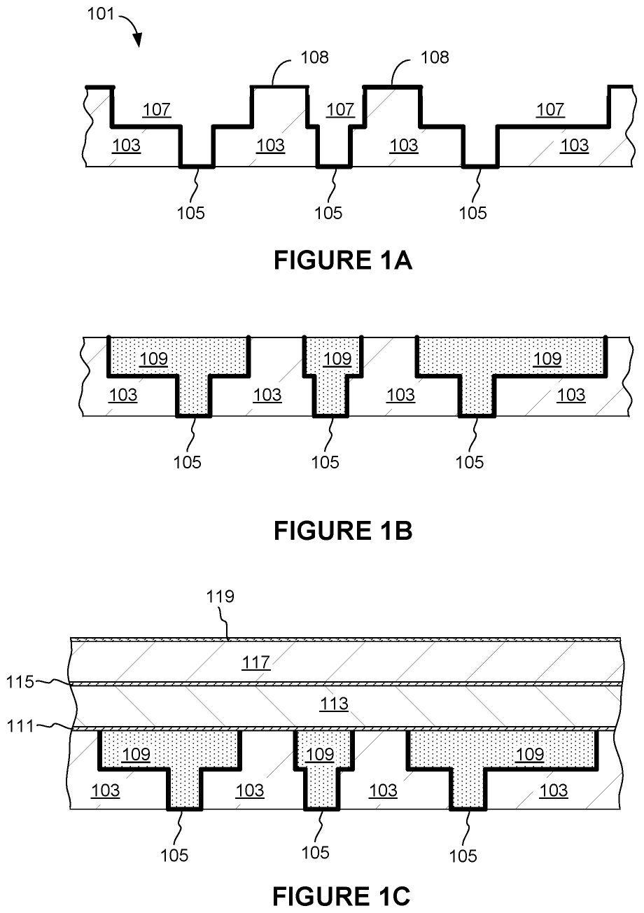

Integrated circuit (IC) fabrication methods commonly involve deposition of metals into recessed features formed in an ILD layer. The deposited metal provides the conductive paths which extend horizontally and/or vertically within the IC. Metal lines formed in adjacent ILD layers may be connected to each other by a series of vias or interconnect features. A stack containing multiple metal lines electrically connected to each other by one or more vias may be formed by a process known as damascene or dual damascene processing. An example of a dual damascene process is described with respect to FIGS. 1A-1E. While the methods, apparatuses, and devices described below may be presented in the context of damascene processing, it will be understood that the methods, apparatuses, and devices of the present disclosure are not limited to only damascene processing and may be used in the context of other processing methods.

FIGS. 1A-1E show cross-sectional schematic illustrations of an example fabrication of semiconductor device structures using a dual damascene fabrication process according to some implementations. Though the dual damascene fabrication process is described in terms of copper, it will be understood that other metals may be used. In FIG. 1A, an example of a substrate 101 used for dual damascene processing is illustrated. In some implementations, the substrate 101 may reside on a layer carrying active devices, such as transistors, or on an underlying metallization layer containing copper or other type of metallization. In some implementations, the substrate 101 may be a semiconductor wafer, built on a semiconductor wafer, or part of a semiconductor wafer. The substrate 101 may include a first dielectric layer 103. In some implementations, the first dielectric layer 103 includes a fluorine-doped or carbon-doped silicon oxide or an organic-containing low-k material such as an organosilicate glass (OSG). The first dielectric layer 103 may include recesses 107 providing etched line paths through the first dielectric layer 103, where the recesses 107 may include vias and trenches. The first dielectric layer 103 may also include field regions 108 outside of the recesses 107. A diffusion barrier layer 105 may be formed on the substrate surface. The diffusion barrier layer 105 may be formed within the recesses 107 and in the field regions 108. The diffusion barrier layer 105 may serve to protect the first dielectric layer 103 and underlying active devices from diffusion of copper. Examples of diffusion barrier materials include but are not limited to titanium (Ti), tantalum (Ta), tantalum nitride (TaN), titanium nitride (TiN), and fluorine-free tungsten (FFW). The diffusion barrier layer 105 may be deposited in the recesses 107 and the field regions 108 by any suitable deposition technique such as physical vapor deposition (PVD), atomic layer deposition (ALD), chemical vapor deposition (CVD), and plasma enhanced chemical vapor deposition (PECVD).

In FIG. 1B, the recesses 107 providing the etched line paths are filled with copper. Conventionally, a thin copper seed layer is deposited on the diffusion barrier layer 105 followed by bulk electrodeposition of copper to fill the recesses 107. This forms a first copper layer 109 within the recesses 107. As used herein, metal layers such as the first copper layer 109 may also be referred to as metallization layers, metal lines, or line features. The recesses 107 that are filled may have aspect ratios equal to or greater than about 2:1, equal to or greater than about 5:1, or equal to or greater than about 10:1. In some implementations, a planarization operation such as chemical mechanical planarization (CMP) may follow after filling the recesses 107 so that any copper overburden is removed. In some implementations, the diffusion barrier layer 105 is removed from the field regions 108 of the first dielectric layer 103. In some implementations, the first copper layer 109 is annealed by exposing the substrate 101 to a high temperature.

In FIG. 1C, subsequent metallization layers are formed over the first copper layer 109 by initially depositing a second dielectric layer 113 over the first dielectric layer 103 and a third dielectric layer 117 over the second dielectric layer 113. Typically, a barrier layer 111 is deposited over the first dielectric layer 103 and the first copper layer 109 to encapsulate conductive routing to the first copper layer 109. The barrier layer 111 may include one or both of a diffusion barrier layer and a liner layer. The second dielectric layer 113 may be deposited on the barrier layer 111 and is typically a low-k dielectric. The second dielectric layer 113 may be part of a dual damascene structure. An etch stop layer 115 may be deposited on the second dielectric layer 113 and a third dielectric layer 117 may be deposited over the etch stop layer 115 to form another part of the dual damascene structure. In some implementations, the third dielectric layer 117 may be a low-k dielectric and may be the same or different material than the second dielectric layer 113.

In FIG. 1D, openings 121 and trenches 123 are etched through the second dielectric layer 113 and the third dielectric layer 117. Openings 121 may be etched through the second dielectric layer 113 and trenches may be etched through the third dielectric layer 117 using standard lithography techniques. Openings 121 may be propagated through the etch stop layer 115, the second dielectric layer 113, and the barrier layer 111.

In FIG. 1E, openings 121 and trenches 123 are coated or lined with a diffusion barrier 125 and subsequently filled with copper to form a second copper layer 127. The diffusion barrier 125 may include one or both of a diffusion barrier layer and a liner layer, where the diffusion barrier 125 may limit diffusion of copper into the second dielectric layer 113 and/or the third dielectric layer 117. The openings 121 and trenches 123 are filled with copper using a suitable deposition technique to form the second copper layer 127. An example of a suitable deposition technique may include electroplating or electroless plating to fill the openings 121 and trenches 123. The first copper layer 109 and the second copper layer 127 are electrically connected and form conductive pathways. Openings 121 filled with copper may provide a via electrically connecting the second copper layer 127 with the first copper layer 109. The first copper layer 109 and the second copper layer 127 form an electrically conductive structure, namely a dual damascene structure. In some implementations, an upper portion of the second copper layer 127 constitutes a copper line formed in the trench 123 and a lower portion of the second copper layer 127 constitutes a copper interconnect feature (e.g., via) formed in the opening 121.

Electrically conductive structures typically include line features that traverse a distance across a chip and via features that connect lines in different levels. Damascene or dual damascene processing may be used to connect lines in different levels. In order to improve semiconductor device performance, feature sizes are becoming smaller and smaller. As a result, interconnect features and vias have also shrunk. This presents many challenges during fabrication and maintaining device performance and reliability.

Generally, when connecting lines in different levels, standard deposition techniques and lithography techniques are utilized. By way of an illustration, a conventional photolithography technique defines features of an electrically conductive structure using patterning and etching processes. In these processes, a photoresist material is deposited on a substrate and then is exposed to light filtered by a reticle. The reticle is generally a glass plate that is patterned with feature geometries that block light from propagating through the reticle. After passing through the reticle, the light contacts the surface of the photoresist material and changes the chemical composition of the photoresist material such that a developer can remove a portion of the photoresist material. A developer is applied to the photoresist material to remove the portion of the photoresist material. The patterned photoresist material is used as a mask to etch underlying layers.

With shrinking feature sizes, the scaling of conventional lithography processes to provide smaller feature sizes can be difficult. This is due at least in part to alignment errors or overlay errors between features in an electrically conductive structure. Alignment errors or overlay errors invariably result during a lithography process as a mask may not be perfectly aligned with an underlying structure. For example, during light exposure stages using a reticle in a photolithography process, there can be misalignment by a few nanometers in patterning masks for vias and trenches. As a result, a via intended to connect a top metal line with a bottom metal line may be misaligned. Although overlay errors can be minimized by reworking the lithography process, some amount of overlay errors is unavoidable. In FIG. 1E, for example, the second copper layer 127 is shown to be misaligned with the first copper layer 109. This kind of misalignment can be more significant as feature sizes shrink.

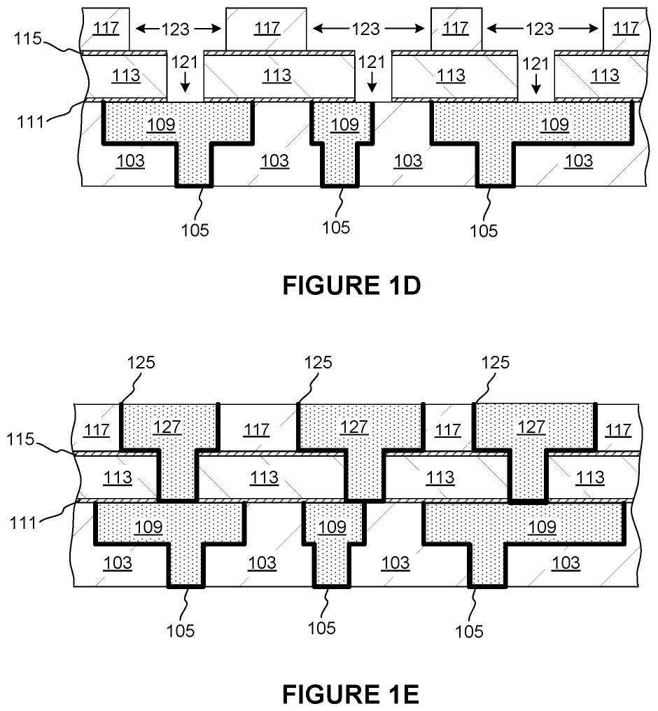

FIG. 2 shows a cross-sectional schematic illustration of an unlanded interconnect feature for an electrically conductive structure. A substrate 201 includes a first dielectric layer 203 having first metal lines 209A and 209B extending partially or fully through the first dielectric layer 203. The first metal lines 209A and 209B may be lined with at least a first barrier layer 205 to limit diffusion of metal into the first dielectric layer 203. Though FIG. 2 shows a single layer for the first barrier layer 205, it will be understood that the first barrier layer 205 may include multiple layers such as a diffusion barrier layer and a liner layer.

The substrate 201 may further include a second metal line 227 over the first metal lines 209A and 209B. As used herein, the second metal line 227 may also be referred to as a top metal line, metallization layer, metal layer, or line feature, and the first metal lines 209A and 209B may also be referred to as bottom metal lines, metallization layers, metal layers, or line features. A via 221 connects the second metal line 227 to an underlying first metal line 209A. The second metal line 227 and the via 221 may be lined with at least a second barrier layer 225 to limit diffusion of metal into a surrounding dielectric layer (not shown). Though FIG. 2 shows a single layer for the second barrier layer 225, it will be understood that the second barrier layer 225 may include multiple layers such as a diffusion barrier layer and a liner layer.

Due to overlay and alignment errors discussed above, the via 221 partially “lands” on a top surface of the underlying first metal line 209A, thereby shifting the via 221 closer to a neighboring first metal line 209B. This leads to a reduced distance 250 between conductive features, meaning that there is less insulating space between the via 221 and the neighboring first metal line 209B. When the via 221 partially lands on the top surface of the underlying first metal line 209A, this may be referred to as an “unlanded via.” This can mean that the via 221 provides landed portions on the underlying first metal line 209A and unlanded portions outside the underlying first metal line 209A.

The reduced distance 250 can lead to an insufficient shorting margin and decreased time-dependent dielectric breakdown (TDDB), or even a complete short-circuit. TDDB is a failure mode whereby an insulating layer (such as the first dielectric layer 203) no longer serves as an adequate electrical insulator in typical electric fields. TDDB is dependent on the electric field between metal features as regions exposed to higher electric fields are more susceptible to TDDB failure. Higher voltages may lead to higher electric fields. TDDB is also dependent on the spacing between metal features as the spacing can be reduced to the point where the insulating layer is incapable of withstanding the electric fields, thereby resulting in unintended conductance between the metal features. The end result is shorting or decreased reliability when the insulating layer is incapable of supporting the operating electric field. Unlanded vias can lead to significant reliability issues because of TDDB degradation.

Self-aligned via patterning schemes may align a via with a top metal line. However, such patterning schemes may be insufficient for aligning a top metal line with a bottom metal line. Fully aligned via patterning schemes not only align a via with top metal line, but also align top metal lines with bottom metal lines in an electrically conductive structure. In other words, a fully aligned via results in a via that is fully aligned with a bottom metal line on a Mₓ level and a top metal line on an Mₓ₊₁ level. A fully aligned via contacts a top surface of a bottom metal line (Mₓ) with no overlap and contacts a bottom surface of a top metal line (Mₓ₊₁) with no overlap. Fully aligned via patterning schemes also address TDDB degradation concerns caused by unlanded vias.

### Fully Aligned Via Patterning Schemes

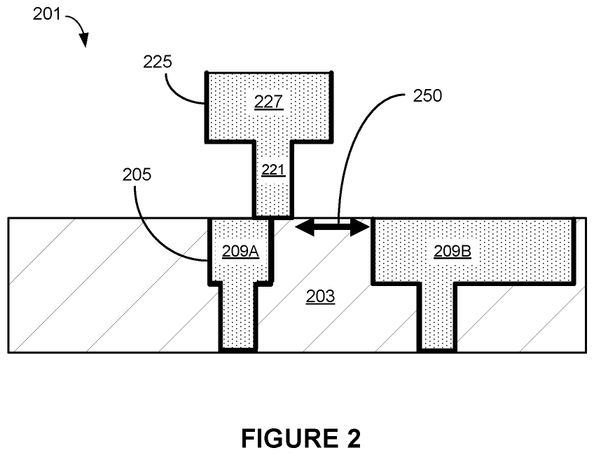

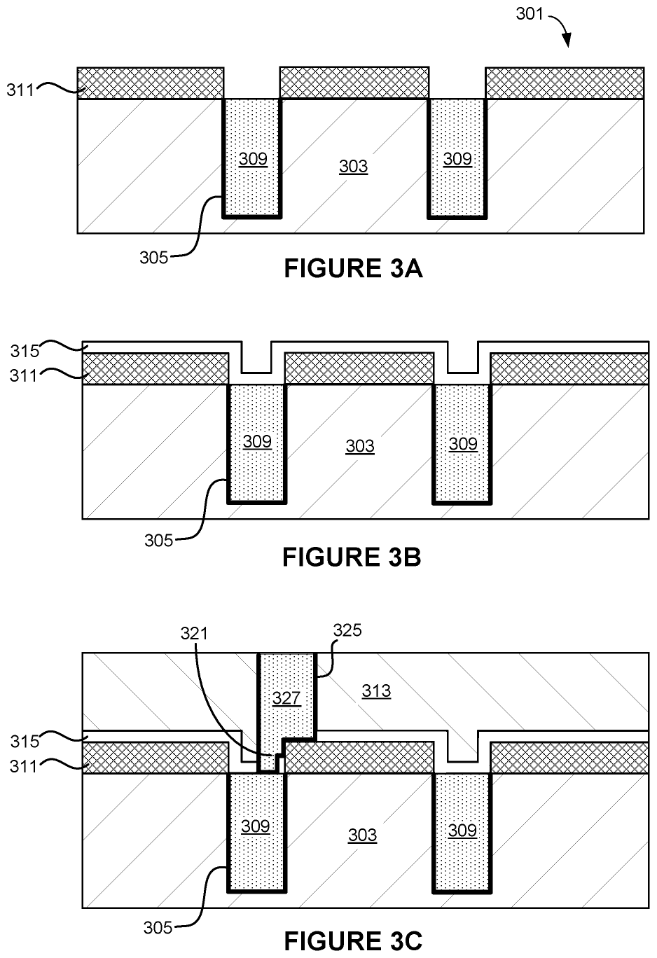

Two examples of fully aligned via patterning schemes are discussed below with respect to FIGS. 3A-3C and FIGS. 4A-4C. It will be understood that fully aligned via patterning schemes in FIGS. 3A-3C and FIGS. 4A-4C are illustrative only and the present disclosure is not limited to these patterning schemes, but the present disclosure may be applied in other fully aligned via patterning schemes.

FIGS. 3A-3C show cross-sectional schematic illustrations of an example process of forming a fully aligned via for connecting metal lines according to some implementations. In FIG. 3A, a substrate 301 includes a first dielectric layer 303. The first dielectric layer 303 may also be referred to as an interlayer dielectric or insulating layer. In some implementations, the first dielectric layer 303 includes a low-k dielectric material such as a fluorine-doped or carbon-doped silicon oxide, or an OSG. A first metal line 309 may be formed in recesses or openings in the first dielectric layer 303, where the first metal line 309 may include an electrically conductive material such as copper, cobalt, ruthenium, aluminum, tungsten, nickel, or alloys thereof. A first barrier layer 305 may line an interface between the first metal line 309 and the first dielectric layer 303. In some implementations, the first barrier layer 305 includes a diffusion barrier layer made of a material such as tantalum or tantalum nitride. In some implementations, the first barrier layer 305 includes a diffusion barrier layer made of a material such as tantalum or tantalum nitride and also a liner layer made of a material such as cobalt or ruthenium. Diffusion barrier layers and liner layers may be formed using any suitable deposition method such as PVD, ALD, CVD, or PECVD.

In FIG. 3A, the substrate 301 further includes a selective dielectric layer 311 formed on the first dielectric layer 303. The selective dielectric layer 311 is not formed on the first metal line 309 and is in a region of the first dielectric layer 303 that is outside where the first metal line 309 is formed. Thus, the first metal line 309 may be formed in recesses or openings through the selective dielectric layer 311 and the first dielectric layer 303, where a top surface of the first metal line 309 is below a top surface of the selective dielectric layer 311. The selective dielectric layer 311 may include a dielectric material that is highly selective. In other words, the selective dielectric layer 311 may include a dielectric material that is highly resistant against many different etchants or etching schemes. In some implementations, the selective dielectric layer 311 includes a masking material such as silicon carbide (SiCₓ), silicon nitride (SiNₓ), or silicon carbonitride (SiCNₓ). The selective dielectric layer 311 may be formed on the first dielectric layer 303 using any suitable deposition method such as PVD, ALD, CVD, or PECVD. In some implementations, the selective dielectric layer 311 may have a thickness between about 1 nm and about 100 nm.

In FIG. 3B, a conformal dielectric layer 315 is formed over the selective dielectric layer 311 and the first metal line 309. The conformal dielectric layer 315 may include a dielectric material having a different etch selectivity than the selective dielectric layer 311. In some implementations, the etch selectivity of the conformal dielectric layer 315 with respect to the selective dielectric layer 311 is equal to or greater than about 10:1, equal to or greater than about 20:1, or equal to or greater than about 50:1, or between about 10:1 and about 100:1. The etch selectivity between the conformal dielectric layer 315 and the selective dielectric layer 311 can be established with dry etching. In some implementations, the conformal dielectric layer 315 may serve as a barrier material against electromigration of metal into adjacent dielectric material. In some implementations, the conformal dielectric layer 315 includes a dielectric material such as silicon carbide (SiCₓ), silicon nitride (SiNₓ), or silicon carbonitride (SiCNₓ). The conformal dielectric layer 315 may be formed on the selective dielectric layer 311 and the first metal line 309 using any suitable deposition method such as PVD, ALD, CVD, or PECVD. The conformal dielectric layer 315 may be conformally deposited, for example, using ALD. In some implementations, the conformal dielectric layer 315 may have a thickness between about 5 nm and about 55 nm.

In FIG. 3C, a second dielectric layer 313 is formed over the conformal dielectric layer 315. The second dielectric layer 313 may also be referred to as an interlayer dielectric or insulating layer. In some implementations, the second dielectric layer 313 includes a low-k dielectric material such as a fluorine-doped or carbon-doped silicon oxide, or an OSG. The conformal dielectric layer 315 may serve as a diffusion barrier layer against electromigration of metal from the first metal line 309 into the second dielectric layer 313. Portions of the second dielectric layer 313 and the conformal dielectric layer 315 are etched to form a recess or opening through the second dielectric layer 313 and the conformal dielectric layer 315 to a top surface of the first metal line 309. The selective dielectric layer 311 serves as an etch stop when the recess or opening is formed through the second dielectric layer 313 and the conformal dielectric layer 315. However, as shown in FIG. 3C, it will be understood that a residual amount of the conformal dielectric layer 315 may remain along sidewalls of the selective dielectric layer 311 after etching portions of the second dielectric layer 313 and the conformal dielectric layer 315. A second metal line 327 and a via 321 connected to the second metal line 327 are formed in the recess or opening by filling the recess or opening with an electrically conductive material such as copper, cobalt, ruthenium, aluminum, tungsten, nickel, or alloys thereof. In some implementations, the recess or opening may be filled using a suitable deposition method such as electroplating or electroless plating. The via 321 may provide electrical interconnection between the first metal line 309 and the second metal line 327. The via 321 is fully aligned with both the first metal line 309 and the second metal line 327. Put another way, the via 321 that is fully aligned does not form an overlap with any dielectric layer adjacent to the first metal line 309 or the second metal line 327. The via 321 contacts the top surface of the first metal line 309 with no overlap on the first dielectric layer 303, and contacts a bottom surface of the second metal line 327 with no overlap on the second dielectric layer 313, and there is no reduced insulating space caused by the via 321 with a neighboring metal line. A second barrier layer 325 may line an interface between the second metal line 327 and the second dielectric layer 313, an interface between the second metal line 327 and the first metal line 309, an interface between the second metal line 327 and the selective dielectric layer 311, and an interface between the second metal line 327 and the conformal dielectric layer 315. In some implementations, the second barrier layer 325 includes a diffusion barrier layer made of a material such as tantalum or tantalum nitride. In some implementations, the second barrier layer 325 includes a diffusion barrier layer made of a material such as tantalum or tantalum nitride and also a liner layer made of a material such as cobalt or ruthenium. Diffusion barrier layers and liner layers may be formed using any suitable deposition method such as PVD, ALD, CVD, or PECVD.

Though the via 321 is fully aligned with the first metal line 309 and the second metal line 327, the via 321 may be considered as partially landed on the top surface of the first metal line 309. The via 321 may provide landed portions on the first metal line 309 and unlanded portions outside the first metal line 309. A surface area of the via 321 contacting the top surface of the first metal line 309 is reduced as a result of the via 321 partially landing on the first metal line 309. Furthermore, the second barrier layer 325 is disposed at an interface between the via 321 and the first metal line 309, thereby adding an electrically insulating material between the via 321 and the first metal line 309. Electrical resistance is directly proportional to a resistivity of a material and its length, and inversely proportional to a cross-sectional area of the material. Thus, the reduced surface area contacting the first metal line 309 and the presence of an electrically insulating material (i.e., second barrier layer 325) at the interface between the via 321 and the first metal line 309 contribute to a higher overall electrical resistance in the via 321. This can be more significant with shrinking feature sizes. Though a fully aligned via patterning scheme may address TDDB degradation concerns as a result of unlanded vias, a fully aligned via patterning scheme may still result in a high via resistance. Such a high via resistance can be detrimental to device performance and reliability.

FIGS. 4A-4C show cross-sectional schematic illustrations of an example process of forming a fully aligned via for connecting metal lines according to some other implementations. Whereas FIGS. 3A-3C show an example of a fully aligned via patterning scheme using a selective dielectric layer to form a stepped topography over first (bottom) metal lines, FIGS. 4A-4C show an example of a fully aligned via patterning scheme using recessed metal in the first (bottom) metal lines to form a stepped topography.

In FIG. 4A, a substrate 401 includes a first dielectric layer 403. The first dielectric layer 403 may also be referred to as an interlayer dielectric or insulating layer. In some implementations, the first dielectric layer 403 includes a low-k dielectric material such as a fluorine-doped or carbon-doped silicon oxide, or an OSG. A first metal line 409 may be formed in recesses or openings in the first dielectric layer 403, where the first metal line 409 may include an electrically conductive material such as copper, cobalt, ruthenium, aluminum, tungsten, nickel, or alloys thereof. A first barrier layer 405 may line an interface between the first metal line 409 and the first dielectric layer 403. In some implementations, the first barrier layer 405 includes a diffusion barrier layer made of a material such as tantalum or tantalum nitride. In some implementations, the first barrier layer 405 includes a diffusion barrier layer made of a material such as tantalum or tantalum nitride and also a liner layer made of a material such as cobalt or ruthenium. Diffusion barrier layers and liner layers may be formed using any suitable deposition method such as PVD, ALD, CVD, or PECVD.

In FIG. 4A, a portion of the first metal line 409 is removed so that a top surface of the first metal line 409 is recessed below a top surface of the first dielectric layer 403. In other words, a stepped topography is formed by recessing the first metal line 409 with respect to the first dielectric layer 403. In some implementations, removal of the portion of the first metal line 409 may involve a wet etch process that causes the first metal line 409 and the first barrier layer 405 to be recessed below a top surface of the first dielectric layer 403.

In FIG. 4B, a conformal dielectric layer 415 is formed over the first dielectric layer 403 and the first metal line 409. The conformal dielectric layer 415 may include a dielectric material having a different etch selectivity than the first dielectric layer 403. In some implementations, the etch selectivity of the conformal dielectric layer 415 with respect to the first dielectric layer 403 is equal to or greater than about 10:1, equal to or greater than about 20:1, equal to or greater than about 50:1, or between about 10:1 and about 100:1. The etch selectivity between the conformal dielectric layer 415 and the first dielectric layer 403 can be established with dry etching. In some implementations, the conformal dielectric layer 415 may serve as a barrier material against electromigration of metal into adjacent dielectric material. In some implementations, the conformal dielectric layer 415 includes a dielectric material such as silicon carbide (SiCₓ), silicon nitride (SiNₓ), or silicon carbonitride (SiCNₓ). The conformal dielectric layer 415 may be formed on the first dielectric layer 403 and the first metal line 409 using any suitable deposition method such as PVD, ALD, CVD, or PECVD. The conformal dielectric layer 415 may be conformally deposited, for example, using ALD. In some implementations, the conformal dielectric layer 415 may have a thickness between about 5 nm and about 55 nm.

In FIG. 4C, a second dielectric layer 413 is formed over the conformal dielectric layer 415. The second dielectric layer 413 may also be referred to as an interlayer dielectric or insulating layer. In some implementations, the second dielectric layer 413 includes a low-k dielectric material such as a fluorine-doped or carbon-doped silicon oxide, or an OSG. The conformal dielectric layer 415 may serve as a diffusion barrier layer against electromigration of metal from the first metal line 409 into the second dielectric layer 413. Portions of the second dielectric layer 413 and the conformal dielectric layer 415 are etched to form a recess or opening through the second dielectric layer 413 and the conformal dielectric layer 415 to the top surface of the first metal line 409. The first dielectric layer 403 serves as an etch stop when the recess or opening is formed through the second dielectric layer 413 and the conformal dielectric layer 415. However, as shown in FIG. 4C, it will be understood that a residual amount of the conformal dielectric layer 415 may remain along sidewalls of the first dielectric layer 403 after etching portions of the second dielectric layer 413 and the conformal dielectric layer 415. A second metal line 427 and a via 421 connected to the second metal line 427 are formed in the recess or opening, by filling the recess or opening with an electrically conductive material such as copper, cobalt, ruthenium, aluminum, tungsten, nickel, or alloys thereof. In some implementations, the recess or opening may be filled using a suitable deposition method such as electroplating or electroless plating. The via 421 may provide electrical interconnection between the first metal line 409 and the second metal line 427. The via 421 is fully aligned with both the first metal line 409 and the second metal line 427. Put another way, the via 421 that is fully aligned does not form an overlap with any dielectric layer adjacent to the first metal line 409 or the second metal line 427. The via 421 contacts the top surface of the first metal line 409 with no overlap on the first dielectric layer 403, and contacts a bottom surface of the second metal line 427 with no overlap on the second dielectric layer 413, and there is no reduced insulating space caused by the via 421 with a neighboring metal line. A second barrier layer 425 may line an interface between the second metal line 427 and the second dielectric layer 413, an interface between the second metal line 427 and the first metal line 409, and an interface between the second metal line 427 and the conformal dielectric layer 415. In some implementations, the second barrier layer 425 includes a diffusion barrier layer made of a material such as tantalum or tantalum nitride. In some implementations, the second barrier layer 425 includes a diffusion barrier layer made of a material such as tantalum or tantalum nitride and also a liner layer made of a material such as cobalt or ruthenium. Diffusion barrier layers and liner layers may be formed using any suitable deposition method such as PVD, ALD, CVD, or PECVD.

Like the via 321 in FIG. 3C, the via 421 in FIG. 4C is fully aligned with the first metal line 409 and the second metal line 427 and partially lands on the top surface of the first metal line 409. And like the via 321 in FIG. 3C, the via 421 in FIG. 4C has a reduced surface area contacting the first metal line 409 and an electrically insulating material (i.e., the second barrier layer 425) at the interface between the via 421 and the first metal line 409, each of which contributes to a higher overall electrical resistance in the via 421.

### Metal Prefill

The present disclosure relates to a metal prefill that directly contacts a first (bottom) metal line without a barrier and/or liner layer interfacing between a via and the first (bottom) metal line. The metal prefill may be a copper via prefill in a fully aligned via patterning scheme, such as a fully aligned via patterning scheme in FIGS. 3A-3C or a fully aligned via patterning scheme in FIGS. 4A-4C. The metal prefill serves as an electrically conductive interconnection between a top metal line and a bottom metal line. Despite the metal prefill having a reduced surface area contacting the bottom metal line in a fully aligned via, there is no electrically insulating material at the interface between the via and the bottom metal line, which reduces the overall electrical resistance in the via.

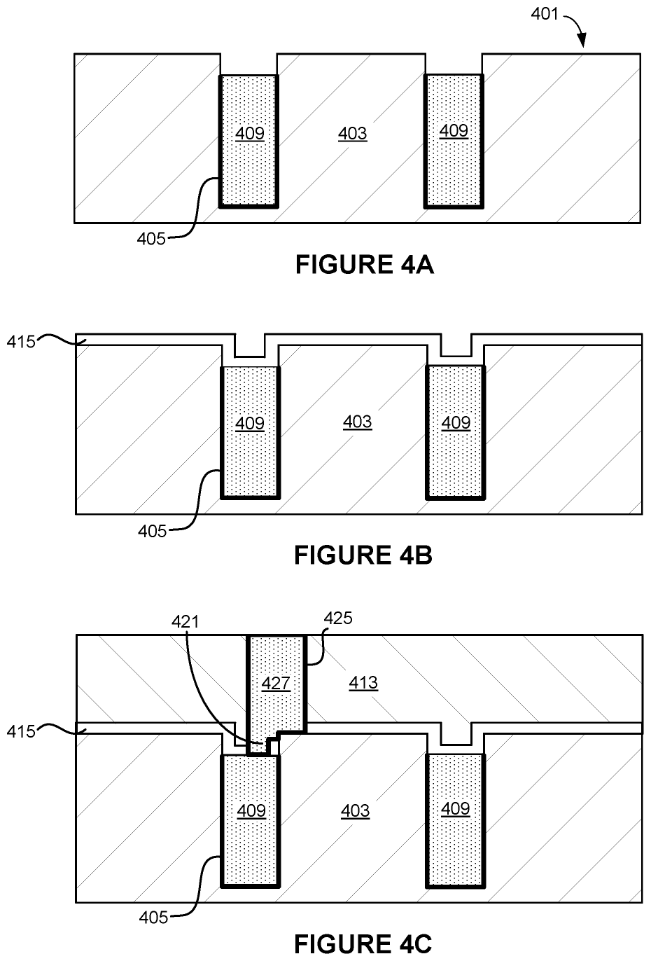

FIG. 5 shows a cross-sectional schematic illustration of an example electrically conductive structure with a via that is a fully aligned via and that is in direct contact with a metal line according to some implementations. An electrically conductive structure 501 is formed according to a fully aligned via patterning scheme reflected in FIGS. 3A-3C. The electrically conductive structure 501 may be formed on a substrate and may be part of an integrated circuit or semiconductor device. The electrically conductive structure 501 includes a first dielectric layer 503 with a first metal line 509 formed in recesses or openings in the first dielectric layer 503. The first metal line 509 may also be referred to as a bottom metal line, metallization layer, metal layer, or line feature. A first barrier layer 505 may provide a diffusion barrier layer and/or liner layer at an interface between the first metal line 509 and the first dielectric layer 503. A selective dielectric layer 511 is disposed on the first dielectric layer 503 in a region of the first dielectric layer 503 outside where the first metal line 509 is formed. This may provide a stepped topography so that the first metal line 509 is recessed below a top surface of the selective dielectric layer 511. The electrically conductive structure 501 further includes a conformal dielectric layer 515 on the selective dielectric layer 511 and the first metal line 509. The electrically conductive structure 501 further includes a second dielectric layer 513 over the conformal dielectric layer 515. Aspects of the first dielectric layer 503, the first barrier layer 505, the first metal line 509, the selective dielectric layer 511, the conformal dielectric layer 515, and the second dielectric layer 513 may be described in FIGS. 3A-3C.

A recess or opening is formed through the second dielectric layer 513 and the conformal dielectric layer 515. The recess or opening is partially filled with an electrically conductive material to form a via 521. The via 521 may also be referred to as an interconnect feature, interconnect structure, metal via prefill, or via prefill. The electrically conductive material of the via 521 may include copper, cobalt, ruthenium, aluminum, tungsten, nickel, or alloys thereof. For example, the via 521 may include copper or copper zinc alloy. There is no diffusion barrier layer and/or liner layer interfacing between the via 521 and the first metal line 509. Thus, the electrically conductive material of the via 521 directly contacts the first metal line 509. This reduces a via resistance compared to vias having a diffusion barrier layer and/or liner layer at an interface between a via and a bottom metal line. The electrically conductive structure 501 further includes a second metal line 527 over the via 521. A remainder of the recess or opening is filled after the via prefill, where the remainder of the recess or opening is filled with an electrically conductive material such as copper, cobalt, ruthenium, aluminum, tungsten, nickel, or alloys thereof to form the second metal line 527. The via 521 may be fully aligned with the second metal line 527 and the first metal line 509. In some implementations, the via 521 provides landed portions on the first metal line 509 and unlanded portions outside the first metal line 509 and on the selective dielectric layer 511.

In some implementations, a diffusion barrier layer 525a and/or a liner layer 525b may line an interface between the second metal line 527 and the second dielectric layer 513 and an interface between the second metal line 527 and the via 521. The diffusion barrier layer 525a and/or liner layer 525b may serve to limit electromigration of metal (e.g., copper) into the second dielectric layer 513. The diffusion barrier layer 525a and the liner layer 525b may be individually or collectively referred to as a second barrier layer. The diffusion barrier layer 525a and the liner layer 525b may be formed after the via prefill and before forming the second metal line 527.

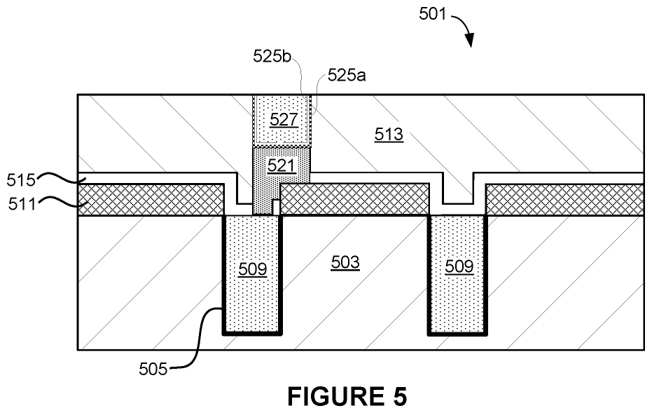

FIG. 6 shows a cross-sectional schematic illustration of an example electrically conductive structure with a via that is a fully aligned via and that is in direct contact with a metal line according to some other implementations. An electrically conductive structure 601 is formed according to a fully aligned via patterning scheme reflected in FIGS. 4A-4C. The electrically conductive structure 601 may be formed on a substrate and may be part of an integrated circuit or semiconductor device. The electrically conductive structure 601 includes a first dielectric layer 603 with a first metal line 609 formed in recesses or openings in the first dielectric layer 603. The first metal line 609 may also be referred to as a bottom metal line, metallization layer, metal layer, or line feature. A first barrier layer 605 may provide a diffusion barrier layer and/or liner layer at an interface between the first metal line 609 and the first dielectric layer 603. The first metal line 609 may be recessed below a top surface of the first dielectric layer 603 to provide a stepped topography. The electrically conductive structure 601 further includes a conformal dielectric layer 615 on the first dielectric layer 603 and the first metal line 609. The electrically conductive structure 601 further includes a second dielectric layer 613 over the conformal dielectric layer 615. Aspects of the first dielectric layer 503, the first barrier layer 505, the first metal line 509, the selective dielectric layer 511, the conformal dielectric layer 515, and the second dielectric layer 513 may be described in FIGS. 3A-3C.

A recess or opening is formed through the second dielectric layer 613 and the conformal dielectric layer 615. The recess or opening is partially filled with an electrically conductive material to form a via 621. The via 621 may also be referred to as an interconnect feature, interconnect structure, metal via prefill, or via prefill. The electrically conductive material of the via 621 may include copper, cobalt, ruthenium, aluminum, tungsten, nickel, or alloys thereof. For example, the via 621 may include copper or copper zinc alloy. There is no diffusion barrier layer and/or liner layer interfacing between the via 621 and the first metal line 609. Thus, the electrically conductive material of the via 621 directly contacts the first metal line 609. This reduces a via resistance compared to vias having a diffusion barrier layer and/or liner layer at an interface between a via and a bottom metal line. The electrically conductive structure 601 further includes a second metal line 627 over the via 621. A remainder of the recess or opening is filled after the via prefill, where the remainder of the recess or opening is filled with an electrically conductive material such as copper, cobalt, ruthenium, aluminum, tungsten, nickel, or alloys thereof to form the second metal line 627. The via 621 may be fully aligned with the second metal line 627 and the first metal line 609. In some implementations, the via 621 provides landed portions on the first metal line 609 and unlanded portions outside the first metal line 609 and on the first dielectric layer 603.

In some implementations, a diffusion barrier layer 625a and/or a liner layer 625b may line an interface between the second metal line 627 and the second dielectric layer 613 and an interface between the second metal line 627 and the via 621. The diffusion barrier layer 625a and/or liner layer 625b may serve to limit electromigration of metal (e.g., copper) into the second dielectric layer 613. The diffusion barrier layer 625a and the liner layer 625b may be individually or collectively referred to as a second barrier layer. The diffusion barrier layer 625a and the liner layer 625b may be formed after the via prefill and before forming the second metal line 627.

The electrically conductive structures 501, 601 include vias 521, 621 that directly interface with the top surface of first metal lines 509, 609 without having a diffusion barrier layer and/or liner layer. Generally, having such a diffusion barrier layer and/or liner layer serves several functions or is expected to serve several functions. As discussed below, the diffusion barrier layer and/or liner layer may serve to slow diffusion of metal into adjacent dielectric material, improve TDDB lifetime, improve adhesion, and limit the formation of stress-induced voids, among other functions. Surprisingly, the absence of having a diffusion barrier layer and/or liner layer with the vias 521, 621 did not necessarily detriment the aforementioned functions or the performance of the integrated circuit or semiconductor device.

A via providing electrical interconnection between a bottom metal line and a top metal line may have a diffusion barrier layer and/or liner layer to slow diffusion of metal atoms (e.g., copper atoms) into surrounding dielectric material. When an electrical current is applied, electrons flow through electrically conductive structures by flowing through the top metal lines and the bottom metal lines. Electromigration is caused by the gradual movement of ions between electrons and diffusing metal atoms. The diffusion of metal into the surrounding dielectric material may adversely affect the electrically insulating properties of the surrounding dielectric material. The diffusion of metal may also undesirably result in the formation of voids in the vias or in the metal lines. A via generally has a diffusion barrier layer and/or liner layer to slow the diffusion of metal into the surrounding dielectric material. However, without being limited by any theory, the presence of a diffusion barrier layer and/or liner layer in the bottom metal lines and the top metal lines may be sufficient to slow diffusion of metal without having to incorporate a diffusion barrier layer and/or liner layer at an interface between a via and a bottom metal line. In some implementations, the presence of a diffusion barrier layer and/or liner layer in the bottom metal lines and the top metal lines may be sufficient to slow diffusion of metal without having to incorporate a diffusion barrier layer and/or liner layer at a bottom surface of a via and along sidewalls of the via.

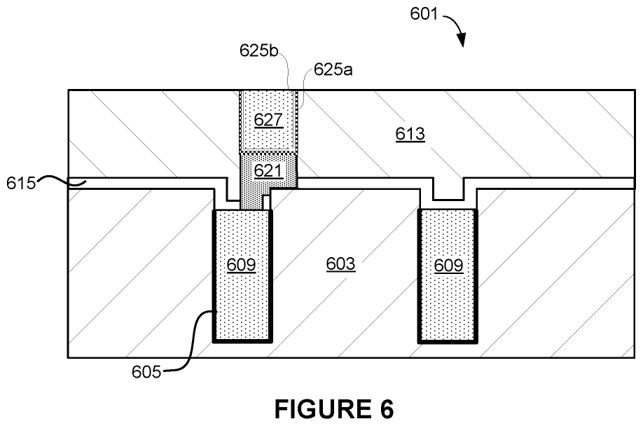

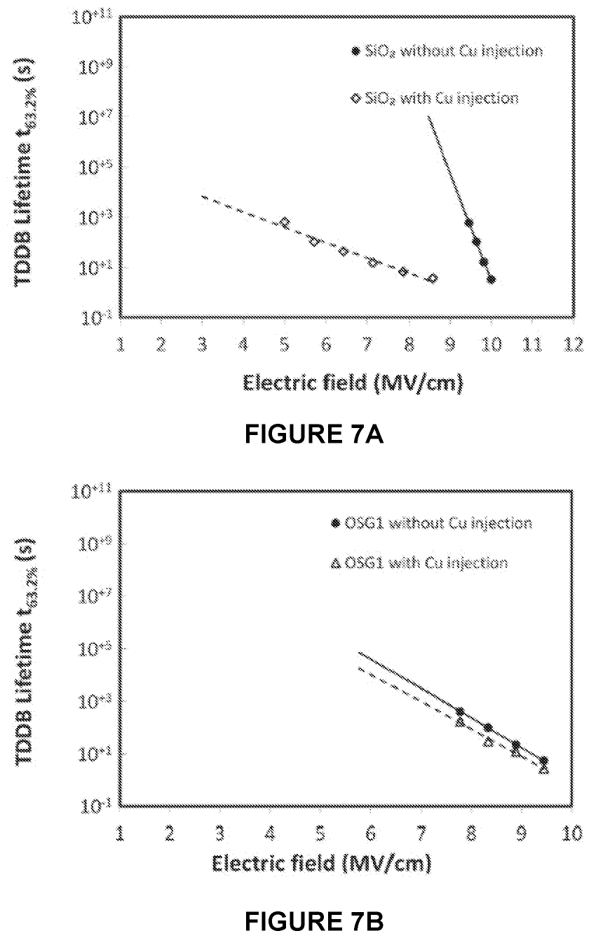

A via providing electrical interconnection between a bottom metal line and a top metal line may have a diffusion barrier layer to improve TDDB lifetime. When metal atoms diffuse into the surrounding dielectric material, the insulating properties of the surrounding dielectric material may be degraded so that it may not be as tolerant of higher electric fields. Thus, limiting the diffusion of metal atoms into the surrounding dielectric material may increase the reliability and performance of an electrically conductive structure. FIG. 7A shows a plot of TDDB lifetime as a function of increasing electric fields for silicon oxide dielectric layers with a barrier layer and without a barrier layer. FIG. 7B shows a plot of TDDB lifetime as a function of increasing electric fields for organosilicate glass dielectric layers with a barrier layer and without a barrier layer. When the surrounding dielectric material is pure silicon oxide (SiOₓ), then the TDDB lifetime is relatively long with increasing electric fields for a copper interconnect structure with a barrier layer (e.g., TaN), but the TDDB lifetime is relatively short with increasing electric fields for a copper interconnect structure without such a barrier layer. When the surrounding dielectric material is an OSG, such as a porous OSG, then the TDDB lifetime is relatively long with increasing electric fields regardless of whether the copper interconnect structure has a barrier layer (e.g., TaN) or not. Without being limited by any theory, the porosity and the carbon doping in the surrounding dielectric material may serve to limit copper diffusion into the surrounding dielectric material that would otherwise cause TDDB degradation.

A via providing electrical interconnection between a bottom metal line and a top metal line may have a diffusion barrier layer to limit the formation of stress-induced voids. Stress-induced voiding may form in a metal interconnect structure over time and/or with the application of higher temperatures. Vacancies in the metal interconnect structure may accumulate and form voids that could result in device failure. Such voids may also increase the overall electrical resistance in the metal interconnect structure. Vacancies may be more likely to accumulate to form voids where there is less volume to move, such as at an interface between a bottom metal line and a via and at an interface between a top metal line and the via. However, without being limited by any theory, having at least the interface between the bottom metal line and the via made of the same material (e.g., copper) can reduce the stress gradient, which can thereby reduce the likelihood of stress-induced voids being formed.

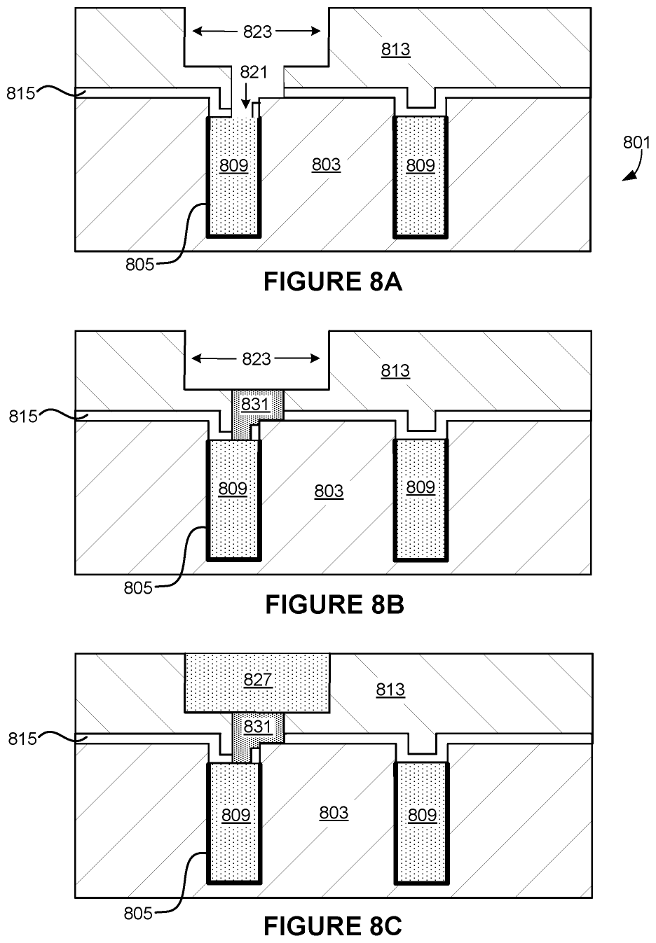

FIGS. 8A-8C show cross-sectional schematic illustrations of an example dual damascene fabrication process with a copper via in direct contact with a copper line according to some implementations. An electrically conductive structure 801 may be part of an integrated circuit with a multi-level structure or a dual damascene structure. The electrically conductive structure 801 may include a first dielectric layer 803. A first copper line 809 may be disposed in a recess or opening of the first dielectric layer 803. The first copper line 809 may also be referred to as a top copper line, copper layer, or copper line feature. A first barrier layer 805 may line an interface between the first copper line 809 and the first dielectric layer 803. The electrically conductive structure 801 may include a conformal dielectric layer 815 over the first dielectric layer 803 and the first copper line 809 and may further include a second dielectric layer 813 over the conformal dielectric layer 815. Though the electrically conductive structure 801 may be fabricated according to a fully aligned via patterning scheme according to FIGS. 4A-4C, it will be understood that the electrically conductive structure 801 may be fabricated according to any suitable fully aligned via patterning scheme such as the fully aligned via patterning scheme shown in FIGS. 3A-3C.

In some implementations, the dielectric material of the second dielectric layer 813 may be a low-k dielectric material. In some implementations, the low-k dielectric material is porous. In some implementations, the low-k dielectric material is characterized by having a dielectric constant of less than about 4.0. Examples of low-k dielectric materials may include fluorinated silicate glass (FSG), organosilicate glass (OSG), and carbon-doped silicon oxide (SiOC). For example, the second dielectric layer 813 may include OSG.

In FIG. 8A, a trench 823 may be formed in an upper portion of the second dielectric layer 813 and an opening 821 may be formed from a bottom of the trench 823 to the first copper line 809. In some implementations, the trench 823 and the opening 821 may be formed according to an example dual damascene fabrication process shown in FIGS. 1A-1E. The first copper line 809 is exposed by the opening 821. In some implementations, the opening 821 may have a high aspect ratio or a high depth-to-width ratio. In some implementations, an aspect ratio of the opening 821 may be greater than about 5:1, or greater than about 10:1, or greater than about 30:1. The trench 823 and the opening 821 are to be filled with an electrically conductive material such as copper to provide electrical interconnection between the first copper line 809 and a higher-level copper line. This provides a dual damascene structure for the electrically conductive structure 801.

The trench 823 and the opening 821 are patterned and formed using standard lithography processes. As a result of alignment errors discussed earlier, patterning the trench 823 and the opening 821 may not result in having the opening 821 being aligned with the first copper line 809. The opening 821 may be offset from the first copper line 809 so that not all of the bottom of the opening 821 exposes the first copper line 809. An etch stop layer such as the first dielectric layer 803 or a selective dielectric layer (not shown) may prevent an etchant from reducing an insulating space between the opening 821 and a neighboring first copper line 809.

In FIG. 8B, a copper via 831 is formed in the opening 821. The copper via 831 may also be referred to as a copper prefill or interconnect feature. The copper via 831 may directly contact the first copper line 809 without a diffusion barrier layer and/or liner layer interfacing between the first copper line 809 and the copper via 831. In some implementations, the copper via 831 may be formed by depositing a copper seed layer followed by bulk filling the opening 821 with copper. In some implementations, the copper via 831 may be formed by simply bulk filling the opening 821 with copper. In some implementations, the copper via 831 may be formed using electroless deposition (ELD) to fill the opening 821. The exposed top surface of the first copper line 809 may be used to initiate nucleation for the deposition reaction of the ELD process. The deposition of copper to fill the opening 821 may proceed in a bottom-up manner, thereby providing for substantial uniformity in filling the opening 821. The ELD process may be selective to the material of the first copper line 809 and not selective to other materials defining the sidewalls of the opening 821. Any copper overburden may be removed by a planarization process such as a chemical mechanical planarization process. The copper via 831 may be formed without depositing a diffusion barrier layer, liner layer, or any other non-copper layer in the opening 821 before bulk filling the opening 821 with copper.

In FIG. 8C, a second copper line 827 is formed in the trench 823. In some implementations, the second copper line 827 formed in the trench 823 is part of a copper interconnect to a higher-level conductor (not shown) in the electrically conductive structure 801. Accordingly, the second copper line 827 may be formed in the trench 823 continuously with the copper via 831. In some implementations, the second copper line 827 is formed using the same deposition technique as the copper via 831. In some implementations, the second copper line 827 serves as the higher-level conductor in the electrically conductive structure 801. Put another way, the second copper line 827 is not part of a copper interconnect to a higher-level conductor, and the copper via 831 provides electrical interconnection between the first copper line 809 and the second copper line 827. Thus, a diffusion barrier layer and/or liner layer (not shown) may be deposited in the trench 823 prior to forming the second copper line 827. Such a diffusion barrier layer and/or liner layer may be deposited at an interface between the second copper line 827 and the second dielectric layer 813. In some implementations, the diffusion barrier layer is made of a material including tantalum or tantalum nitride and the liner layer is made of a material including ruthenium or cobalt.

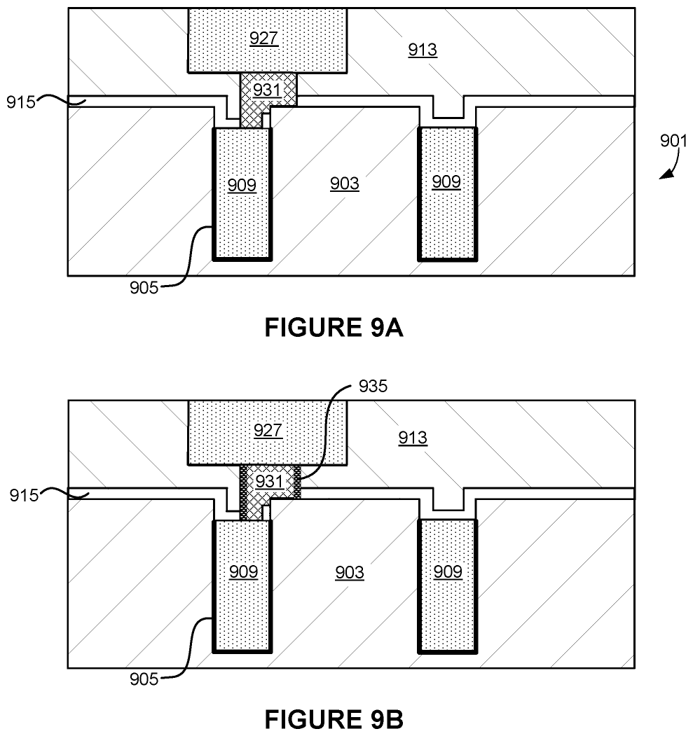

FIGS. 9A-9B show cross-sectional schematic illustrations of an example fabrication process for a copper alloy via in direct contact with a copper line and a self-formed barrier layer according to some implementations. Though an electrically conductive structure 901 may be fabricated according to a fully aligned via patterning scheme according to FIGS. 4A-4C, it will be understood that the electrically conductive structure 901 may be fabricated according to any suitable fully aligned via patterning scheme such as the fully aligned via patterning scheme shown in FIGS. 3A-3C.

The electrically conductive structure 901 in FIG. 9A may be similar to the electrically conductive structure 801 in FIGS. 8A-8C so that aspects of a first dielectric layer 903, a first copper line 909, a first barrier layer 905, a conformal dielectric layer 915, a second dielectric layer 913, and a second copper line 927 may be described in FIGS. 8A-8C. In contrast to FIGS. 8A-8C, a copper alloy via 931 capable of forming a self-formed barrier layer is formed in FIGS. 9A-9B instead of a copper via 831.

In FIG. 9A, a copper alloy is deposited in an opening through at least the second dielectric layer 913 to form the copper alloy via 931. In some implementations, the copper alloy may be deposited in a trench extending partially through the second dielectric layer 913 and above a top surface of the opening. In some implementations, an electrically conductive material such as copper may be deposited in the trench to form the second copper line 927. In some implementations, the copper alloy may be deposited in the opening to form the copper alloy via 931 by ELD. The copper alloy may include but is not limited to copper zinc, copper manganese, copper indium, copper titanium, copper magnesium, copper silver, or copper rhenium. The copper alloy via 931 may be formed without depositing a diffusion barrier layer, liner layer, or any other non-copper layer in the opening before bulk filling the opening with the copper alloy.

In FIG. 9B, the copper alloy is annealed to form a self-formed barrier layer 935 at an interface between the copper alloy via 931 and the second dielectric layer 913. The annealing process can be performed prior to filling the trench or after filling the trench. In some implementations, the annealing process may apply a temperature between about 150° C. and about 400° C. The annealing process may cause segregation of elements in the copper alloy so that some elements diffuse and react with surrounding dielectric material. For example, the zinc may diffuse towards an interface between the copper alloy via 931 and the second dielectric layer 913, where zinc atoms may react with silicon and oxygen atoms in the surrounding dielectric material to form zinc silicate. The self-formed barrier layer 935 may include a reaction product formed between the surrounding dielectric material and the copper alloy material, such as the zinc silicate. The self-formed barrier layer 935 may be a thin barrier that serves to limit diffusion of copper into the second dielectric layer 913.

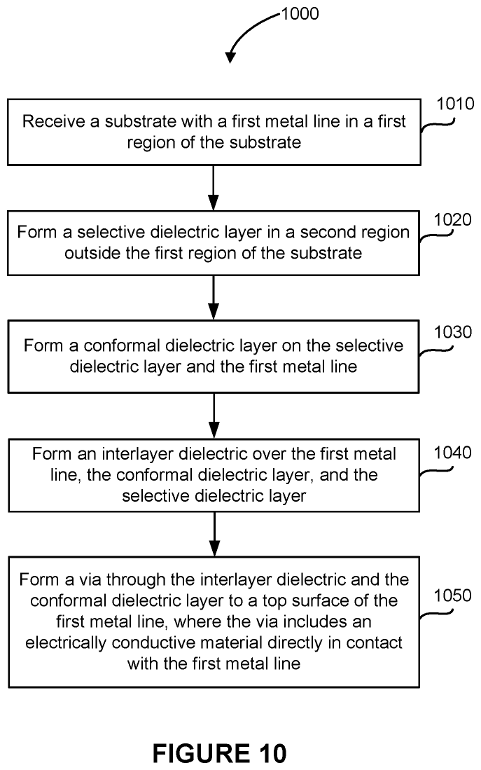

FIG. 10 shows a flow diagram of an example method of manufacturing an electrically conductive structure of an integrated circuit according to some implementations. The operations in a process 1000 may be performed in different orders and/or with different, fewer, or additional operations.

At block 1010 of the process 1000, a substrate with a first metal line in a first region of the substrate is received. The first metal line may be formed in recesses or openings of a dielectric material. In some implementations, the first metal line may include an electrically conductive material such as copper, cobalt, ruthenium, aluminum, tungsten, nickel, or alloys thereof. In some implementations, a diffusion barrier layer and/or a liner layer may be formed at an interface between the first metal line and the dielectric material.

At block 1020 of the process 1000, a selective dielectric layer is formed in a second region outside the first region of the substrate. The first metal line may be recessed so that the first metal line is below a top surface of the selective dielectric layer. The selective dielectric layer may include a low-k dielectric material such as SiCₓ, SiNₓ, or SiCNₓ. The selective dielectric layer may have a high selectivity and may be resistant against many different etchants or etching schemes.

At block 1030 of the process 1000, a conformal dielectric layer is formed on the selective dielectric layer and the first metal line. The conformal dielectric layer may have a different etch selectivity than the underlying selective dielectric layer. In some implementations, the conformal dielectric layer has an etch selectivity equal to or greater than about 10:1 with respect to the selective dielectric layer. The conformal dielectric layer may serve as a barrier layer against electromigration of metal atoms into adjacent dielectric material. The conformal dielectric layer may include a low-k dielectric material such as SiCₓ, SiNₓ, or SiCNₓ. In some implementations, the conformal dielectric layer is conformally deposited using a suitable deposition technique such as ALD.

At block 1040 of the process 1000, an interlayer dielectric is formed over the first metal line, the conformal dielectric layer, and the selective dielectric layer. In some implementations, the interlayer dielectric includes a low-k dielectric material such as FSG, OSG, or SiOC. For example, the low-k dielectric material can include porous OSG.

In some implementations, the process 1000 may substitute blocks 1010-1040 with an operation for receiving a substrate with a first metal line in a first region of the substrate, a selective dielectric layer in a second region outside the first region of the substrate, a conformal dielectric layer on the selective dielectric layer and the first metal line, and an interlayer dielectric over the first metal line, the conformal dielectric layer, and the selective dielectric layer. Such an operation may be performed prior to an operation at block 1050.

At block 1050 of the process 1000, a via is formed through the interlayer dielectric and the conformal dielectric layer to a top surface of the first metal line, where the via includes an electrically conductive material directly in contact with the first metal line. In some implementations, the via is a dual damascene interconnect. In some implementations, forming the via includes forming a trench and an opening through the interlayer dielectric and the conformal dielectric layer, where the opening extends from a bottom of the trench to the top surface of the first metal line. The selective dielectric layer serves as an etch stop or hardmask when forming the opening through the interlayer dielectric and the conformal dielectric layer. The opening may have a high aspect ratio such as an aspect ratio greater than about 5:1, greater than about 10:1, or greater than about 30:1.

In some implementations, forming the via further includes filling the opening with the electrically conductive material to form the via. The opening may be filled using a suitable deposition technique such as ELD. In some implementations, the electrically conductive material can include copper or copper alloy. The electrically conductive material of the via may directly contact the first metal line so that no diffusion barrier layer and/or liner layer is provided at an interface between the via and the first metal line. The absence of a diffusion barrier layer and/or liner layer reduces the overall electrical resistance in the via.

In some implementations, the process 1000 further includes forming a second metal line over the first metal line where the via provides electrical interconnection between the second metal line and the first metal line. The via may be fully aligned with both the first metal line and the second metal line. In some implementations, forming the second metal line includes filling the trench with an electrically conductive material. The electrically conductive material may include copper, cobalt, ruthenium, aluminum, tungsten, nickel, or alloys thereof. In some implementations, the trench may be filled using a suitable deposition technique such as electroplating or ELD. In some implementations, the process 1000 further includes annealing the substrate to form a self-formed barrier layer along sidewalls of the via. In some implementations, a diffusion barrier layer and/or a liner layer may be formed at an interface between the second metal line and the interlayer dielectric. The diffusion barrier layer may include a material such as tantalum or tantalum nitride, and the liner layer may include a material such as ruthenium or cobalt.

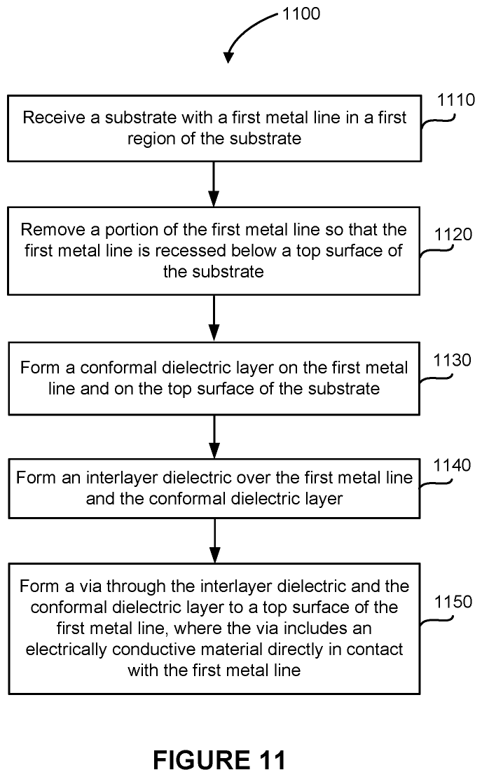

FIG. 11 shows a flow diagram of an example method of manufacturing an electrically conductive structure of an integrated circuit according to some implementations. The operations in a process 1100 may be performed in different orders and/or with different, fewer, or additional operations.

At block 1110 of the process 1100, a substrate with a first metal line in a first region of the substrate is received. The substrate may further include a dielectric material, where the first metal line may be formed in recesses or openings of the dielectric material. In some implementations, the first metal line may include an electrically conductive material such as copper, cobalt, ruthenium, aluminum, tungsten, nickel, or alloys thereof. In some implementations, a diffusion barrier layer and/or a liner layer may be formed at an interface between the first metal line and the dielectric material.

At block 1120 of the process 1100, a portion of the first metal line is removed so that the first metal line is recessed below a top surface of the substrate. In some implementations, a wet etch process may be performed to remove the portion of the first metal line so that the first metal line is recessed below the top surface of the substrate. The top surface of the substrate may constitute a top surface of the dielectric material. As a result, the first metal line may be formed in recesses or openings of the dielectric material so that the first metal line is below the top surface of the dielectric material. Removal of the portion of the first metal line provides a stepped topography on the substrate.

At block 1130 of the process 1100, a conformal dielectric layer is formed on the first metal line and the top surface of the substrate. The top surface of the substrate may include the top surface of the dielectric material. The conformal dielectric layer may have a different etch selectivity than the underlying dielectric material. In some implementations, the conformal dielectric layer has an etch selectivity equal to or greater than about 10:1 with respect to the underlying dielectric material. The conformal dielectric layer may serve as a barrier layer against electromigration of metal atoms into adjacent dielectric material. The conformal dielectric layer may include a low-k dielectric material such as SiCₓ, SiNₓ, or SiCNₓ. In some implementations, the conformal dielectric layer is conformally deposited using a suitable deposition technique such as ALD.

At block 1140 of the process 1100, an interlayer dielectric is formed over the first metal line and the conformal dielectric layer. In some implementations, the interlayer dielectric includes a low-k dielectric material such as FSG, OSG, or SiOC. For example, the low-k dielectric material can include porous OSG.

In some implementations, the process 1100 may substitute blocks 1110-1140 with an operation for receiving a substrate with a first metal line in a first region of the substrate that is recessed below a top surface of the substrate, a conformal dielectric layer on the first metal line and the top surface of the substrate, and an interlayer dielectric over the first metal line and the conformal dielectric layer. Such an operation may be performed prior to an operation at block 1150.

At block 1150 of the process 1100, a via is formed through the interlayer dielectric and the conformal dielectric layer to a top surface of the first metal line, where the via includes an electrically conductive material directly in contact with the first metal line. In some implementations, the via is a dual damascene interconnect. In some implementations, forming the via includes forming a trench and an opening through the interlayer dielectric and the conformal dielectric layer, where the opening extends from a bottom of the trench to the top surface of the first metal line. The dielectric material of the substrate serves as an etch stop or hardmask when forming the opening through the interlayer dielectric and the conformal dielectric layer. The opening may have a high aspect ratio such as an aspect ratio greater than about 5:1, greater than about 10:1, or greater than about 30:1.

In some implementations, forming the via further includes filling the opening with the electrically conductive material to form the via. The opening may be filled using a suitable deposition technique such as ELD. In some implementations, the electrically conductive material can include copper or copper alloy. The electrically conductive material of the via may directly contact the first metal line so that no diffusion barrier layer and/or liner layer is provided at an interface between the via and the first metal line. The absence of a diffusion barrier layer and/or liner layer reduces the overall electrical resistance in the via.

In some implementations, the process 1100 further includes forming a second metal line over the first metal line where the via provides electrical interconnection between the second metal line and the first metal line. The via may be fully aligned with both the first metal line and the second metal line. In some implementations, forming the second metal line includes filling the trench with an electrically conductive material. The electrically conductive material may include copper, cobalt, ruthenium, aluminum, tungsten, nickel, or alloys thereof. In some implementations, the trench may be filled using a suitable deposition technique such as electroplating or ELD. In some implementations, the process 1100 further includes annealing the substrate to form a self-formed barrier layer along sidewalls of the via. In some implementations, a diffusion barrier layer and/or a liner layer may be formed at an interface between the second metal line and the interlayer dielectric. The diffusion barrier layer may include a material such as tantalum or tantalum nitride, and the liner layer may include a material such as ruthenium or cobalt.

The process described herein may be used in conjunction with lithographic patterning tools or processes, for example, for the fabrication or manufacture of semiconductor devices, displays, LEDs, photovoltaic panels and the like. Typically, though not necessarily, such tools/processes will be used or conducted together in a common fabrication facility. Lithographic patterning of a film typically includes some or all of the following operations, each operation enabled with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

### CONCLUSION

In the foregoing description, numerous specific details are set forth to provide a thorough understanding of the presented implementations. The disclosed implementations may be practiced without some or all of these specific details. In other instances, well-known process operations have not been described in detail to not unnecessarily obscure the disclosed implementations. While the disclosed implementations are described in conjunction with the specific implementations, it will be understood that it is not intended to limit the disclosed implementations.

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. An apparatus comprising:
a first dielectric layer;
a first metal line formed in the first dielectric layer;
a second dielectric layer over the first metal line and the first dielectric layer;
a second metal line formed in the second dielectric layer or over the second dielectric layer;
a via extending through the second dielectric layer and electrically connecting the first metal line and the second metal line, wherein the via is fully aligned with the first metal line and the second metal line, and wherein the via includes an electrically conductive material directly in contact with the first metal line; and
a self-formed barrier layer at an interface between the second dielectric layer and the via, wherein the electrically conductive material of the via includes a copper alloy, wherein the copper alloy includes copper zinc and the self-formed barrier layer includes zinc silicate.

2. The apparatus of claim 1, wherein each of the first metal line and the second metal line includes copper or copper alloy.

3. The apparatus of claim 1, wherein the first metal line is recessed below a top surface of the first dielectric layer.

4. The apparatus of claim 1, further comprising:
a conformal dielectric layer disposed over the first dielectric layer and the first metal line, wherein the conformal dielectric layer is between the first dielectric layer and the second dielectric layer.

5. The apparatus of claim 4, further comprising:
a selective dielectric layer disposed on the first dielectric layer so that the first metal line is recessed below a top surface of the selective dielectric layer, wherein the conformal dielectric layer is disposed on the selective dielectric layer and has an etch selectivity of greater than about 10:1 with respect to the selective dielectric layer.

6. The apparatus of claim 4, wherein the via is disposed in a trench and an opening extending through the second dielectric layer and the conformal dielectric layer, wherein the opening extends from a bottom of the trench to a top surface of the first metal line.

7. The apparatus of claim 1, further comprising:
a first barrier layer at an interface between the first metal line and the first dielectric layer; and
a second barrier layer at an interface between the second metal line and the second dielectric layer.

8. The apparatus of claim 7, wherein each of the first barrier layer and the second barrier layer includes a diffusion barrier layer and/or a liner layer.

9. The apparatus of claim 1, wherein the electrically conductive material of the via directly contacts the first metal line without a diffusion barrier layer and/or a liner layer between the via and the first metal line.

10. The apparatus of claim 1, wherein the second dielectric layer includes a low-k dielectric material having a dielectric constant of less than about 4.0.

11. The apparatus of claim 10, wherein the low-k dielectric material includes a porous organosilicate glass (OSG).

12. (canceled)

13. (canceled)

14. The apparatus of claim 1, wherein the via is partially landed on the first metal line to provide landed portions on the first metal line and unlanded portions outside the first metal line.

15. A method of manufacturing an electrically conductive structure, the method comprising:
receiving a substrate with a first metal line in a first region of the substrate, a selective dielectric layer in a second region outside the first region of the substrate, a conformal dielectric layer on the selective dielectric layer and the first metal line, and an interlayer dielectric over the first metal line, the conformal dielectric layer, and the selective dielectric layer, wherein the conformal dielectric layer has an etch selectivity equal to or greater than about 10:1 with respect to the selective dielectric layer;
forming a via through the interlayer dielectric and the conformal dielectric layer to a top surface of the first metal line, wherein the via includes an electrically conductive material directly in contact with the first metal line, wherein the electrically conductive material of the via includes a copper alloy, the copper alloy including copper zinc; and
annealing the substrate to form a self-formed barrier layer at an interface between the interlayer dielectric and the via, wherein the self-formed barrier layer includes zinc silicate.

16. The method of claim 15, further comprising:
forming a second metal line over the first metal line, wherein the via provides electrical interconnection between the second metal line and the first metal line.

17. The method of claim 16, wherein each of the first metal line and the second metal line includes a copper or copper alloy.

18. The method of claim 15, wherein forming the via comprises:
forming a trench and an opening through the interlayer dielectric and the conformal dielectric layer, wherein the opening extends from a bottom of the trench to the top surface of the first metal line; and
filling the opening with the electrically conductive material to form the via.

19. The method of claim 18, wherein filling the opening with the electrically conductive material comprises:
depositing, by electroless deposition, the electrically conductive material on the first metal line.

20. (canceled)

21. A method of manufacturing an electrically conductive structure, the method comprising:
receiving a substrate with a first metal line in a first region of the substrate that is recessed below a top surface of the substrate, a conformal dielectric layer on the first metal line and the top surface of the substrate, and an interlayer dielectric over the first metal line and the conformal dielectric layer, wherein the conformal dielectric layer has an etch selectivity equal to or greater than about 10:1 with respect to an underlying dielectric material of the substrate;
forming a via through the interlayer dielectric and the conformal dielectric layer to a top surface of the first metal line, wherein the via includes an electrically conductive material directly in contact with the first metal line, wherein the electrically conductive material of the via includes a copper alloy, the copper alloy including copper zinc; and
annealing the substrate to form a self-formed barrier layer at an interface between the interlayer dielectric and the via, wherein the self-formed barrier layer includes zinc silicate.

22. The method of claim 21, further comprising:
forming a second metal line over the first metal line, wherein the via provides electrical interconnection between the second metal line and the first metal line.

23. The method of claim 22, wherein each of the first metal line and the second metal line includes a copper or copper alloy.

24. The method of claim 21, further comprising:
forming a trench and an opening through the interlayer dielectric and the conformal dielectric layer, wherein the opening extends from a bottom of the trench to the top surface of the first metal line; and
filling the opening with the electrically conductive material to form the via.

25. The method of claim 24, wherein filling the opening with the electrically conductive material comprises:
depositing, by electroless deposition, the electrically conductive material on the first metal line.

26. (canceled)
